(19) United States
(12) Patent Application Publication
(10) Pub. No.: US 2012/0012898 A1
(43) Pub. Date: Jan. 19, 2012

(54) SOLID STATE IMAGING DEVICE

(76) Inventor: Masatoshi IWAMOTO, Kagoshima (JP)

(21) Appl. No.: 13/182,102

(22) Filed: Jul. 13, 2011

(30) Foreign Application Priority Data
Jul. 14, 2010 (JP) 2010-159967

(51) Int. Cl. H01L 27/148

(52) U.S. Cl. 257/222; 257/E27.15

(57) ABSTRACT

A solid state imaging device includes: a semiconductor substrate having photoelectric conversion regions arranged in matrix, charge transfer regions, and element-separating regions; an insulating film on the semiconductor substrate; transfer electrodes provided in one-to-one with the photoelectric conversion regions and disposed on the insulating film at locations corresponding to the charge transfer regions; and wiring portions each connecting transfer electrodes adjacent in a row direction. The charge transfer regions are doped with impurities so that, in any charge transfer region, a potential of each portion corresponding to an upstream edge of a transfer electrode in the charge transfer direction is lower than the potential of the remaining portions. Each wiring portion connects into a respective transfer electrode at a location offset downstream from the upstream edge of the transfer electrode in the charge transfer direction. The location of each element-separating region corresponds to a respective wiring portion.

The disclosure of Japanese Patent Application No. 2010-159967 filed Jul. 14, 2010 including specification, drawings and claims is incorporated herein by reference in its entirety.

### TECHNICAL FIELD

The present invention relates to solid state imaging devices and in particular to a charge-coupled device (CCD) type solid state imaging device having one electrode per pixel.

### BACKGROUND ART

Solid state imaging devices of the type mentioned above are used in devices including digital cameras and mobile phones (see Patent literature 1, for example). The following describes the structure of a conventional CCD solid state imaging device. FIG. 7 is a schematic view of a conventional solid state imaging device illustrated to show the component arrangement.

As shown in FIG. 7, the conventional solid state imaging device has a plurality of photodiodes 102 arranged in an X-Y matrix in a semiconductor substrate. Along a side edge of each array of photodiodes 102 aligned in the Y-axis (column) direction, a vertical charge coupled device (VCCD) 103 is provided for transferring signal charge of the photodiode array.

In addition, transfer electrodes 104 are provided in a one-to-one relation with the photodiodes 102. More specifically, the transfer electrodes 104 are each disposed at a location corresponding, with an insulating film therebetween, to a region of the semiconductor substrate where a VCCD is located (i.e., between adjacent photodiodes in the X-axis direction). Each transfer electrode reads a signal charge from a corresponding photodiode 102 and transfers the signal charge in the transfer direction shown in FIG. 7. Each two transfer electrodes 104 adjacent in the X-axis direction are connected via a connecting portion 105. In order to separate each two photodiodes 102 adjacent in the Y-axis direction, an element-separating region 106 is provided in a region of the semiconductor substrate corresponding to a connecting portion 105.

### CITATION LIST

### Patent Literature

[Patent Literature 1]

JP patent application publication No. 3-97381

### SUMMARY OF INVENTION

### Technical Problem

In recent years, the market for compact digital cameras has been in strong demand. In order to meet the demand, solid state imaging devices need to be downsized, without compromising the sensitivity. For this reason, some recent solid state imaging devices are provided with photodiodes 102 each having a relatively sufficient area and VCCDs 103 each having a reduced width, so that the miniaturization is achieved without sensitivity reduction. Unfortunately, however, such a recent solid state imaging device is adversely affected by so-called a narrow channel effect. That is, since the width of each VCCD 103 is smaller, thermal diffusion of impurities (such as boron) from the element-separating region 106 toward the VCCDs 103 results in the formation of potential barriers.

In addition, the VCCDs 103 are doped with impurities to form a potential gradients.

FIG. 8 is a view showing a graph of the gradient of potential across a VCCD of a conventional solid state imaging device in a manner that the horizontal axis of the graph corresponds in position to the transfer electrodes. In FIG. 8, a potential gradient D represents the potential gradient observed prior to impurity doping (i.e., the potential gradient formed solely by the element-separating region 106), whereas a potential gradient E represents the potential gradient observed after impurity doping (i.e., the potential gradient formed by the injected impurities and the element-separating region 106).

As indicated by the potential gradient D shown in FIG. 8 relating to the conventional solid state imaging device, potential barriers b3 formed as a result of the narrow channel effect appear in regions of the VCCD 103 corresponding to the upstream edge portion of each transfer electrode 104 in the transfer direction.

In addition, the impurities have been doped into the VCCD 103 so that the potential of each region thereof corresponding to the upstream edge portion of any transfer electrode 104 in the transfer direction is made lower than the potential of the remaining regions. For this reason, as indicated by the potential gradient E, potential barriers b4 resulting from the doped impurities appear in regions of the VCCD 103 corresponding to the upstream edge portion of each transfer electrode 104 in the transfer direction.

As described above, the potential barriers b4 resulting from the doped impurities and the potential barriers b3 resulting from the narrow channel effect both appear in the regions of the VCCD 103 each corresponding to the upstream edge portion of one of the transfer electrodes 104.

However, in the VCCD 103, the potential gradient is relatively gentle in each region corresponding to the central portion of any transfer electrode 104 in the Y-axis direction (region c2 shown in FIG. 8). Consequently, there is a risk that the vertical transfer of signal charge cannot be completed within a transfer time, so that part of the signal charge remains untransferred, which results in insufficient transfer. The risk noted above may be addressed by additionally doping impurities into the VCCD 103 in an attempt to form an adequate gradient at each region corresponding to the central portion of any transfer electrode 104 in the Y-axis direction. However, in view of the fact that doped impurities diffuse, extremely high precision is required in doping impurities into desired regions of the VCCD 103. It is therefore unpractical to form a smoothly varying gradient (i.e., without sudden changes).

The present invention solves the problems noted above and provides a solid state imaging device configured to perform the vertical transfer of signal charge, ensuring that part of the signal charge remaining untransferred is reduced as compared with a conventional device.

### Solution to Problem

In order to solve the problems noted above, a first aspect of the present invention provides a solid state imaging device including: a semiconductor substrate, an insulating film formed on the semiconductor substrate; a plurality of transfer electrodes; and wiring portions. The semiconductor substrate has (i) a plurality of photoelectric conversion regions arranged in a row-and-column matrix, (ii) charge transfer regions each formed between adjacent columns of the photoelectric conversion regions, and (iii) element-separating regions each formed between photoelectric conversion regions adjacent in a column direction. The transfer electrodes are arranged on the insulating film at locations corresponding to the charge transfer regions of the semiconductor substrate. Each transfer electrode is provided in one-to-one relation with one of the photoelectric conversion regions to read a signal charge from a respective photoelectric conversion region and transfer the read signal charge in the column direction. Each wiring portions connects transfer electrodes adjacent in a row direction. The charge transfer regions contains impurities doped so that, in any charge transfer region, a potential of each portion corresponding to an upstream edge of one of the transfer electrodes in a charge transfer direction is lower than remaining portions of the charge transfer region. A location at which each wiring portion connects into a respective transfer electrode is offset downstream from the upstream edge of the transfer electrode in the charge transfer direction. A location of each element-separating region of the semiconductor substrate corresponds to a respective wiring portion.

### Advantageous Effect of the Invention

According to the first aspect of the present invention, the solid state imaging device has the charge transfer regions doped with impurities so that, in any charge transfer region, the potential of each portion corresponding to the upstream edge portion of any of the transfer electrodes in the charge transfer direction is made lower than the potential of the remaining portions. Note that each wiring portion connects into a respective transfer electrode at a location offset downstream from the upstream edge of the transfer electrode. In addition, the element-separating regions of the semiconductor substrate are at locations corresponding to the respective wiring portions. With this arrangement, each potential barrier resulting from the narrow channel effect appears, in a charge transfer region, at a location offset downstream from the upstream edge of a respective transfer electrode, rather than at a location corresponding to the upstream edge of the transfer electrode. As a result, in any charge transfer region, the potential of each region closer to the central portion of any transfer electrode in the column direction is steeper than otherwise it would be. This reduces the amount of signal charge that remains untransferred at the time of vertical transfer, which consequently improves the transfer efficiency.

Here, in another aspect of the present invention, the location offset downstream from the upstream edge of a respective transfer electrode refers to a location between the upstream edge of the transfer electrode and a central portion of the transfer electrode in the column direction.

Here, in yet another aspect of the present invention, in the column direction, each element-separating region is wider than a respective wiring portion located on a region of the insulating film corresponding to the element-separating region.

In the solid state imaging device according to this aspect, each element-separating region is wider in the column direction than a respective wiring portion that is formed on the insulating film at a location corresponding to the element-separating region. This arrangement reduces influence of the electric field induced by the wiring portions.

### BRIEF DESCRIPTION OF THE DRAWINGS

FIG. 1 is a view of a solid state imaging device 100 according to Embodiment 1, schematically showing the component arrangement.

FIG. 2 is an enlarged view of a region a of the solid state imaging device 100 shown in FIG. 1.

FIG. 3 is a view showing a graph of the potential gradient across a charge transfer region 3 in a manner that the horizontal axis of the graph corresponds in position to transfer electrodes 4.

FIG. 4 shows two cross sections of the solid state imaging device 100 according to Embodiment 1 (portion (a) shows a cross section taken along the line A-A′ of FIG. 1, whereas portion (b) shows a cross section taken along the line B-B′ of FIG. 1).

FIG. 5 shows a cross section of the solid state imaging device 100 according to Embodiment 1, taken along the line C-C′ of FIG. 1.

FIGS. 6A, 6B and 6C are views showing exemplary manufacturing steps of the solid state imaging device 100 according to Embodiment 1.

FIG. 7 is a view of a conventional solid state imaging device schematically showing the component arrangement.

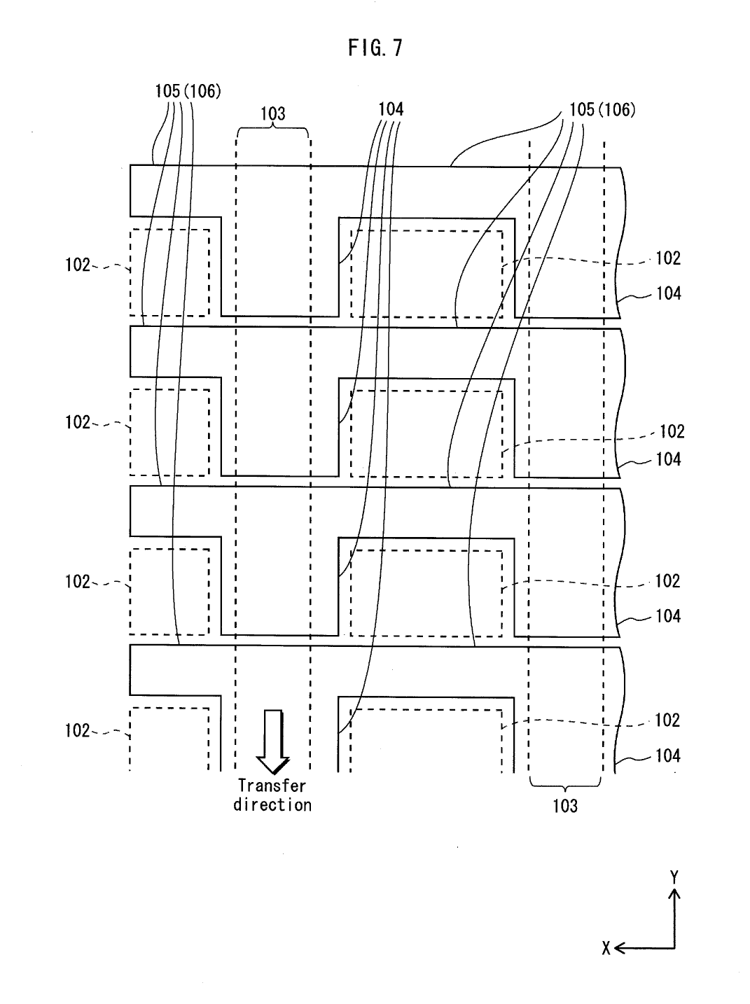

FIG. 8 is a view showing a graph of the potential gradient across a VCCD in a manner that the horizontal axis of the graph corresponds in position to transfer electrodes.

### DESCRIPTION OF THE PREFERRED EMBODIMENTS

### Embodiment 1

1. Component Arrangement of Solid State Imaging Device 100

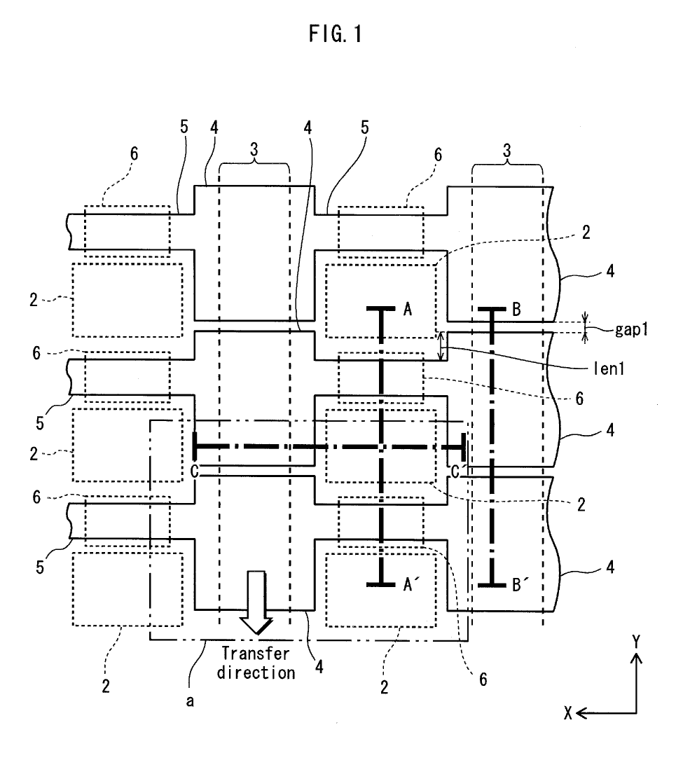

FIG. 1 is a view of a solid state imaging device 100 according to Embodiment 1, schematically showing the component arrangement. In the figure, components formed in a semiconductor substrate are represented by dotted lines, whereas components formed above the semiconductor substrate via a gate insulating film are represented by solid lines. As shown in FIG. 1, a plurality of photoelectric conversion regions 2 are arranged in an X-Y matrix in the semiconductor substrate. Each photoelectric conversion region converts light incident from outside into a signal charge corresponding to the amount of incident light. Along one side edge of each column of photoelectric conversion regions 2 arrayed in the Y-axis (column) direction, a charge transfer region (transfer channel) 3 is provided for transferring signal charges stored in the column of the photoelectric conversion regions 2.

In addition, a transfer electrode 4 is provided between each two photoelectric conversion regions 2 adjacent in the X-axis direction. That is, the transfer electrodes 4 are in one-to-one relation with the photoelectric conversion regions 2. Each transfer electrode reads out a signal charge from a corresponding photoelectric conversion region 2 and transfers the read signal charge in the transfer direction shown in FIG. 1. Preferably, the width of a gap 1 between the transfer electrodes 4 adjacent in the Y-axis direction is, for example, about 0.1 μm in order to avoid occurrence of a potential dip between the adjacent transfer electrodes 4. Each transfer electrode 4 is continuously connected to another transfer electrode 4 adjacent in the X-axis direction with a wiring portion 5 which is integral with the transfer electrodes 4. In the regions of the semiconductor substrate each corresponding to any wiring portion 5, an element-separating region 6 is formed to separate the photoelectric conversion regions 2 adjacent in the Y-axis direction. The width of each element-separating region 6 in the Y-axis direction is greater than the width of a respective wiring portion 5 in the Y-axis direction. Since each element-separating region 6 is wider than a respective wiring portion 5 in the Y-axis direction, the effect on the photoelectric conversion regions 2 imposed by the electric field of the wiring portions 5 is reduced.

With respect to the relative positions of any wiring portion 5 and two transfer electrodes 4 adjacent in the X-axis direction and connected by the wiring portion 5, the upstream edge of the wiring portion 5 is offset downstream (toward the center of the transfer electrode 4 in the Y-axis direction) from the upstream edge of each transfer electrode 4 by the offset distance len1. Therefore, the same holds regarding the relative positions of the transfer electrodes 4 and an element-separating region 6 corresponding to the wiring portion 5. More specifically, the upstream edge of the element-separating region 6 is offset downstream from the upstream edge of each transfer electrode 4. The advantageous effect achieved by the above positional relation will be described later. Preferably, the offset distance len1 falls within the range of 0.1-0.3 μm. More preferably, the offset distance len1 is about 1/4 of the cell size, for example. With the above alignment, the electric field around the center of each transfer electrode 4 is improved without adversely affecting the voltage characteristics exhibited by the photoelectric conversion regions 2 at the time of reading signal charges.

2. Impurity Injection Region in Charge Transfer Region 3

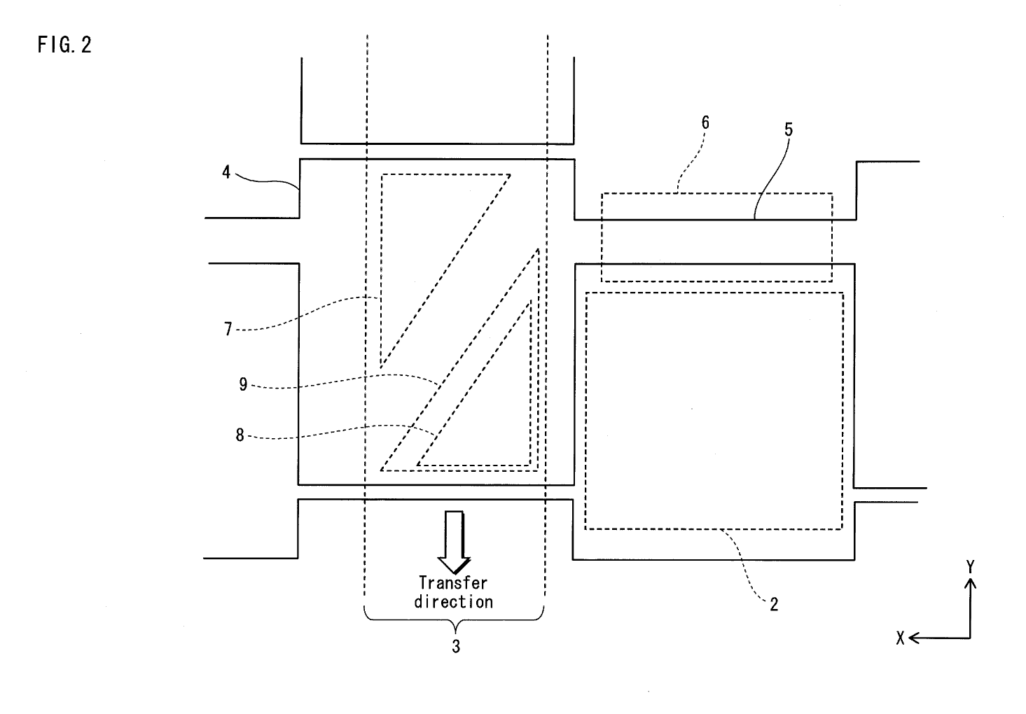

FIG. 2 is an enlarged view of a region a of the solid state imaging device 100 shown in FIG. 1. As shown in FIG. 2, the charge transfer region 3 includes, at a location corresponding to a transfer electrode 4, a boron-doped region 7 which is doped with boron, and a first arsenic-doped region 8 and a second arsenic-doped region 9 each of which is doped with arsenic (hereinafter, the boron-injected region 7 and the first and second arsenic-doped regions 8 and 9 are collectively referred to as “impurity-doped region”).

Note that although FIG. 2 shows the impurity-doped region corresponding to one transfer electrode 4, such an impurity-doped region exist at every location corresponding, within each charge transfer region 3, to a transfer electrode 4. In FIG. 2, in addition, the transfer electrode 4 reads a signal charge from the photoelectric conversion region 2 that is shown on the right of the transfer electrode 4.

The boron-doped region 7 is at a location corresponding to the upstream portion of the transfer electrode 4. The impurity concentration of the doped boron is in the range of 2.0 to 4.0 E16cm⁻³, for example. With respect to the location of any boron-doped region 7 in relation to two photoelectric conversion regions 2 flanking the boron-doped region 7, it is preferable that the boron-doped region 7 is further away from the photoelectric conversion region 2 from which the transfer electrode 4 reads a signal charge than from the other photoelectric conversion region 2. Such a location is preferable for the transfer electrode 4 to avoid reading a signal charge from the other photoelectric conversion region 2 than the photoelectric conversion region 2 targeted for reading.

The first and second arsenic-doped regions 8 and 9 are at locations corresponding to the downstream portion of the transfer electrode 4. The impurity concentration of the arsenic doped in the first arsenic-doped region 8 is in the range of 2.0 to 4.0 E16cm⁻³, for example. Similarly, the impurity concentration of the arsenic doped in the second arsenic-doped region 9 is in the range of 2.0 to 4.0 E16cm⁻³, for example. Preferably, the first and second arsenic-doped regions 8 and 9 are located closer toward the photoelectric conversion region 2 from which the transfer electrode 4 reads a signal charge. Such a location is preferable for the transfer electrode 4 to more reliably read a signal charge from the photoelectric conversion region 2 targeted for reading.

3. Potential Gradient across Charge Transfer Region 3

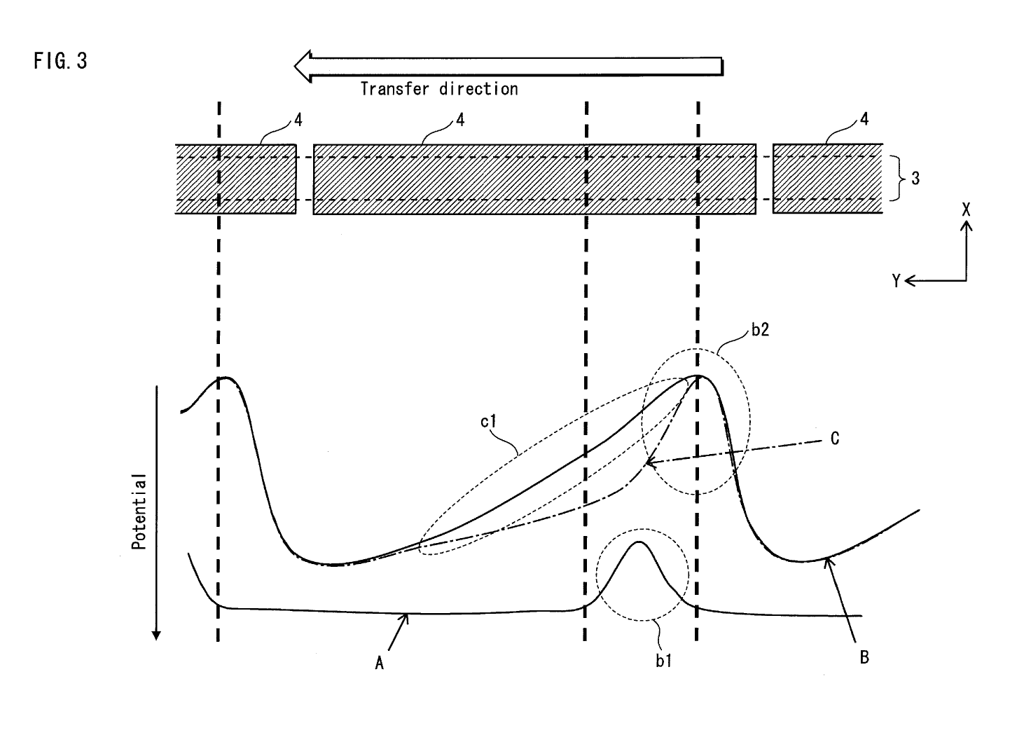

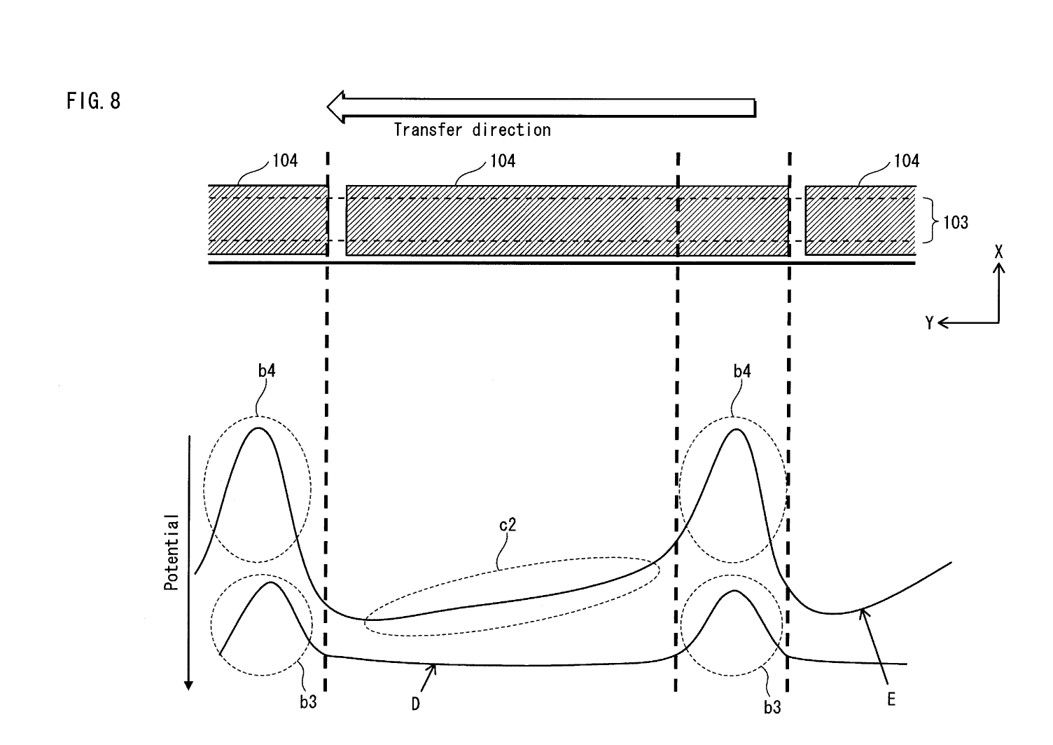

The following describes the gradient of potential developed across each charge transfer region 3 by the impurity-doped regions and the element-separating regions 6. FIG. 3 is a view showing a graph of the gradient of potential across a charge transfer region 3 in a manner that the horizontal axis of the graph corresponds in position to the transfer electrodes 4. In FIG. 3, a potential gradient A represents the potential gradient observed prior to the formation of impurity-doped regions (that is, the potential gradient resulting solely from the element-separating regions 6). A potential gradient B represents the potential gradient observed after the formation of impurity-doped regions (that is, the potential gradient resulting from the impurity-doped regions and the element-separating regions 6). Similarly to the potential gradient E shown in FIG. 8, a potential gradient C represents the potential gradient of a conventional solid state imaging device.

As represented by the potential gradient A, a potential barrier b1 is formed in the charge transfer region 3 as a result of the narrow channel effect due to the element-separating region 6. According to the present embodiment, however, the element-separating region 6 is formed at a location offset downstream from the upstream edge of a corresponding transfer electrode 4. Therefore, the potential barrier b1 also appears at a location offset from the upstream edge of the transfer electrode 4.

In addition, as represented by the potential gradient B, under the influence of the boron-doped region 7, a potential barrier b2 appears at a location corresponding to the upstream edge portion of the transfer electrode 4. To be further noted is that the potential gradient B is steeper than the conventional potential gradient C at a portion corresponding to the central portion of the transfer electrode 4 in the Y-axis direction (i.e., at the portion c1 shown in FIG. 3). This is owing to the narrow channel effect by the element-separating region 6 formed at a location offset downstream from the upstream edge of the transfer electrode 4. Consequently, the risk is reduced of insufficient transfer of signal charge in a region corresponding to the central portion of each transfer electrode 4 in the Y-axis direction, which improves the transfer efficiency.

As described above, each element-separating region 6 is formed at a location offset downstream from the upstream edge of the transfer electrode 4. It is therefore necessary to adjust the amount of boron to be doped into the boron-doped region 7 in order to form a potential barrier as in a conventional manner, i.e., at a portion of the charge transfer region 3 corresponding to the upstream edge portion a transfer electrode.

In addition, by the influence of the first arsenic-doped region 8 and the second arsenic-doped region 9, the potential across each transfer electrode 4 gently rises from a portion near the center to the downstream edge in the Y-axis direction.

4. Structure of Solid State Imaging Device

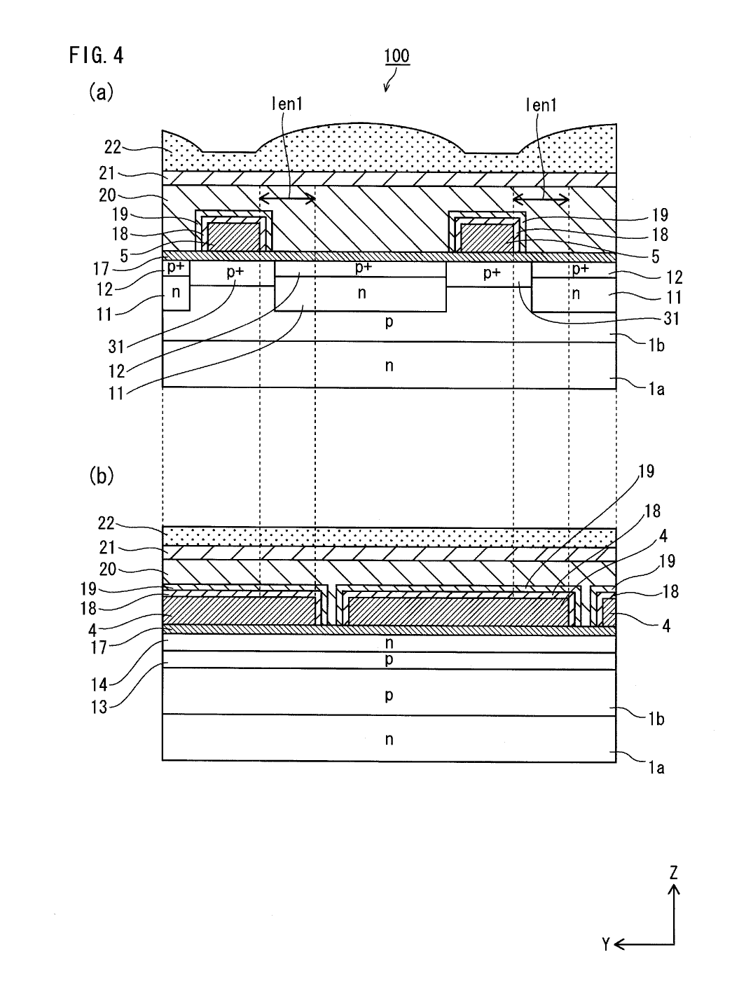

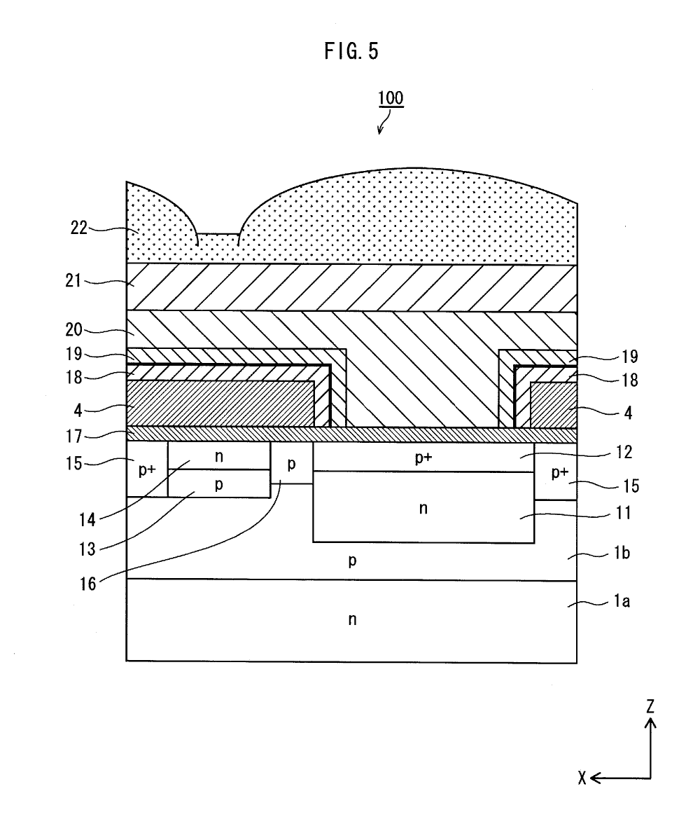

The following describes the structure of the solid state imaging device 100. In FIG. 4, a portion (a) is a sectional view (taken along the line A-A′ of FIG. 1) and a portion (b) is a sectional view (taken along the line B-B′ of FIG. 1) of the solid state imaging device 100 according to Embodiment 1. FIG. 5 is a sectional view of the solid state imaging device 100 according to Embodiment 1 (taken along the line C-C′ of FIG. 1).

As shown in the portions (a) and (b) of FIG. 4, the solid state imaging device 100 according to Embodiment 1 has a gate insulating film 17 made of a silicon nitride film disposed on a main surface (i.e., a surface facing toward the Z-direction) of a semiconductor substrate 1a and also has transfer electrodes 4 and wiring portions 5 made of polysilicon at selective locations on the gate insulating film 17. The transfer electrodes 4 and the wiring portions 5 are coated with a laminate of an inter-layer insulating film 18 and a light-shielding film 19. In addition, a Boron Phosphorous Silicate Glass (BPSG) film 20 is formed to provide a flat surface by filling out the unevenness between the regions where the transfer electrodes 4 and the wiring portions 5 are present and not present. On the BPSG film 20, a color filter 21 is formed. On the color filter 21, a top-lens layer 22 is formed.

As shown in the portions (a) and (b) of FIG. 4 and in FIG. 5, the semiconductor substrate 1a is an n-type silicon substrate having a p-type well region lb formed of p-type impurities on the main surface of the semiconductor substrate 1a. The following describes the p-type well region lb in detail, with reference to the portion (a) of FIG. 4A and to FIG. 5.

As shown in the portion (a) of FIG. 4, the p-type well region lb includes: first n-type semiconductor well regions 11; high-concentration, first p-type semiconductor well regions 12 each formed on a first n-type semiconductor well region 11; and high-concentration, first p-type element-separating region 31 each formed at a location adjacent to the interface between a first n-type semiconductor well region 11 and a first p-type semiconductor well region 12.

As shown in FIG. 5, the p-type well region 1b also includes: high-concentration, second p-type element-separating regions 15 each formed at a location adjacent to the interface between a first n-type semiconductor well region 11 and a first p-type semiconductor well region 12; second p-type semiconductor well regions 13 each formed at a location away from both the first n-type semiconductor well regions 11 and the first p-type semiconductor well regions 12; second n-type semiconductor well regions 14 each formed on a second p-type semiconductor well region 13; and third p-type element-separating regions 16 each formed at a location adjacent to the interface between a second p-type semiconductor well region 13 and a second n-type semiconductor well region 14.

Each second n-type semiconductor well region 14 constitutes a charge transfer region 3 and measures, for example, within a range of 0.15 to 0.35 μm in width in the X-axis direction and within a range of 0.05 to 0.1 μm in depth. The second n-type semiconductor well regions 14 are formed by doping arsenic and the impurity concentration of doped arsenic falls within the range of 4.0 to 6.0 E17cm⁻³, for example. As shown in the portion (b) of FIG. 4 and in FIG. 5, the transfer electrodes 4 are formed on the gate insulating film 17 at locations corresponding to the second n-type semiconductor well regions 14.

In addition, each first p-type element-separating region 31 constitutes an element-separating region 6. Preferably, the width of each first p-type element-separating region 31 in the Y-axis direction is equal to or wider than the width of each wiring portion 5 in the Y-axis direction. For example, the range of 0.1 to 0.4 μm is preferable. As shown in the portion (a) of FIG. 4, each first p-type element-separating region 31 is formed within the well region 1b of the semiconductor substrate 1a and at a location corresponding to a wiring portion 5.

In order for causing a narrow channel effect, the width between a first p-type element-separating region 31 and a second n-type semiconductor well region 14 in the X-axis direction preferably falls between the range of 0.025 to 0.1 μm or so.

As is apparent also from the portions (a) and (b) of FIG. 4, the location of each wiring portion 5 is offset from the upstream edge of a corresponding transfer electrode 4 by the offset distance len1, rather than at the upstream edge of the transfer electrode 4. Similarly, the location of each first p-type element-separating region 31 is offset in the same manner.

5. Method for Manufacturing Solid State Imaging Device

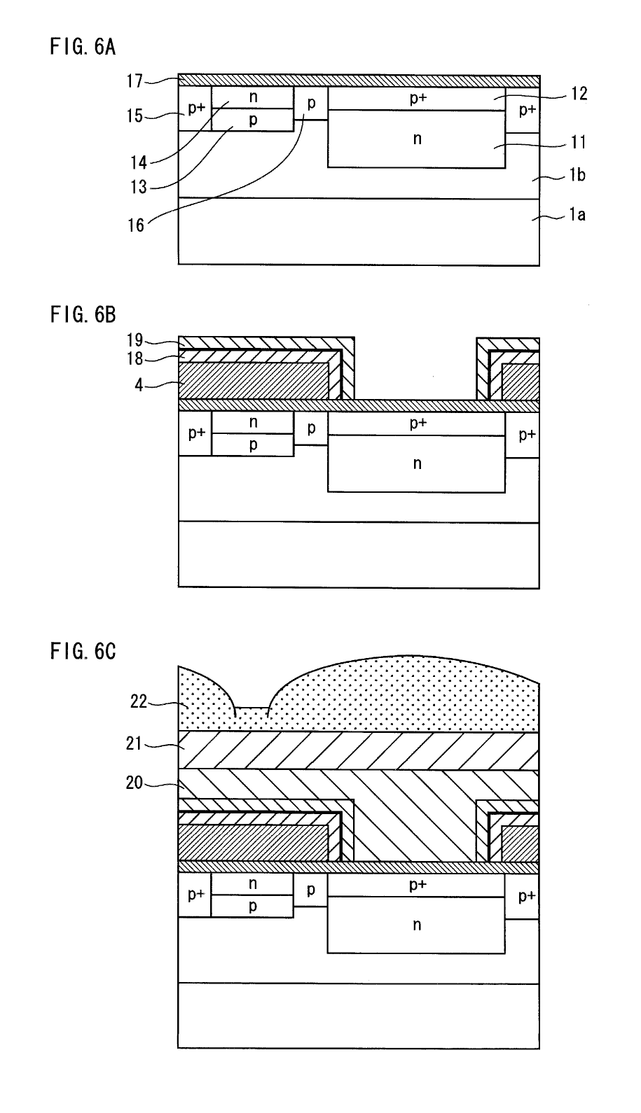

The following describes a method for manufacturing the solid state imaging device 100. FIGS. 6A-6C are cross-sectional views showing the solid state imaging device 100 in each manufacturing step.

First, a gate insulating film 17 is formed on a semiconductor substrate 1a. Then, p-type impurities are doped into the front surface region of the semiconductor substrate 1a to form a p-type well region 1b. Then, first n-type semiconductor well regions 11 and first p-type semiconductor well regions 12 are formed within the p-type well region 1b. Well regions are formed by ion implantation, for example.

Next, second p-type semiconductor well regions 13 and second n-type semiconductor well regions 14 are formed by, for example, ion implantation into the p-type well region 1b at locations away from the first n-type semiconductor well regions 11 and the first p-type semiconductor well regions 12. In addition, first p-type element-separating regions 31 (not shown) and second p-type element-separating regions 15, and third p-type element-separating regions 16 are formed by, for example, ion implantation (boron as impurities, for example). Through the above manufacturing steps, the state as shown in FIG. 6A is achieved. Note that the concentration of boron contained in the first p-type element-separating regions 31 is made to fall within the range of 1e13 to 2e13/cm³. This boron concentration needs to be satisfied in order to avoid degradation in the separation ability of the first p-type element-separating regions 31, each of which is located at a position within the p-type well region lb and corresponding to any wiring portions 5, in view of the fact that voltage is applied to the wiring portions 5 when charges held by the photoelectric conversion regions 2 are read. The boron concentration mentioned above is also effective to take advantage of the narrow channel effect imposed on the second n-type semiconductor well regions 14.

Next, a transfer electrode layer is formed by depositing, for example, a polycrystalline Si film on the gate insulating film 17, followed by deposition of an oxide film on the polycrystalline Si film. Note that the transfer electrode layer may be a metal gate and still achieves a comparable effect.

Subsequently, a resist film is deposited on the oxide film and a stripe pattern is transferred to the resist film. The stripe pattern is defined, for example, to have openings at locations corresponding to gaps between transfer electrodes to be formed. Through dry-etching of that follows, unwanted portions of the oxide film alone are removed. Note that each gap between the transfer electrodes is, for example, 0.1 pm or so as described above. Then, the resist film is peeled off and a resist film is deposited again. The pattern having openings at locations corresponding to the photoelectric conversion regions 2 to be formed is transferred onto the resist film, followed by dry-etching to remove unwanted portions of the oxide film only and subsequently by peeling off of the resist film. Next, the remaining portions of the oxide film are used as a hard mask in dry-etching to remove unwanted portions of the polycrystalline Si film. Through the above manufacturing steps, the transfer electrodes 4 and the wiring portions 5 are formed at the same time, which is effective to simplify the entire manufacturing process.

Then, inter-layer insulating films 18 are formed on the transfer electrodes 4 and wiring portions 5 and then a light-shielding film 19 is formed on each inter-layer insulating film 18. Through the above manufacturing steps, the state as shown in FIG. 6B is achieved.

Next, a BPSG film 20 is formed to provide a flat surface by filling out unevenness between where the transfer electrodes 4 and the wiring portions 5 are present and where the transfer electrodes 4 and the wiring portions 5 are not present. Then, a color filter 21 is formed on the BPSG film 20 and a top-lens layer 22 are formed on the color filter 21. Through the above manufacturing steps, the state as shown in FIG. 6C is achieved.

As has been described above, according to the present embodiment, the charge transfer regions 3 are doped with impurities so that, in any charge transfer region 3, the potential of each portion corresponding to an upstream edge of a transfer electrode 4 in a charge transfer direction is lower than the potential of the remaining portions of the charge transfer region 3. In addition, each wiring portion 5 connecting adjacent transfer electrodes 4 is at a location offset downstream from the upstream edge of the respective transfer electrodes 4. Further, each element-separating regions 6 formed in the semiconductor substrate 1a is at a location corresponding to a wiring portion 5. With this arrangement, in the charge transfer regions 3, each potential barrier resulting from a narrow channel effect appears at a location offset from the upstream edge of a transfer electrode 4, rather than at a location corresponding to the upstream edge of the transfer electrode 4. As a result, in each charge transfer region 3, the potential gradient of each region closer to the central portion of any transfer electrode 4 in the Y-axis direction is steeper than otherwise it would be. Such potential gradients are effective to avoid insufficient vertical transfer of signal charge and thus to improve the transfer efficiency.

<Supplemental Note>

Up to this point, a solid state imaging device according to the present invention has been described by way of the embodiment. However, it is naturally appreciated that the present invention is not limited to the specific embodiment described above.

In the above embodiment, the transfer electrodes 4 and the wiring portions 5 are both made of polysilicon through the same processing step(s). Alternatively, however, the wiring portions 5 may be made of metal such as tungsten and disposed above the transfer electrodes 4. This modification is effective to reduce the resistance of the wiring portions 5.

### INDUSTRIAL APPLICABILITY

The present invention is widely applicable to solid state imaging devices and especially useful in solid state imaging devices having photoelectric conversion regions and transfer electrodes that are formed in one-to-one relation.

### REFERENCE SIGNS LIST

1a semiconductor substrate
1b p-type well region
2 photoelectric conversion region
3 charge transfer region
4 transfer electrode
5 wiring portion
6 first p-type element-separating region
11 first n-type semiconductor well region
12 first p-type semiconductor well region
13 second p-type semiconductor well region
14 second n-type semiconductor well region
31 first p-type element-separating region
15 second p-type element-separating region
16 third p-type element-separating region
17 gate insulating film
18 inter-layer insulating film
19 light-shielding film
20 BPSG film
21 color filter
22 top-lens layer

What is claimed is:

1. A solid state imaging device comprising:
a semiconductor substrate having (i) a plurality of photoelectric conversion regions arranged in a row-and-column matrix, (ii) charge transfer regions each formed between adjacent columns of the photoelectric conversion regions, and (iii) element-separating regions each formed between photoelectric conversion regions adjacent in a column direction;
an insulating film formed on the semiconductor substrate;
a plurality of transfer electrodes arranged on the insulating film at locations corresponding to the charge transfer regions of the semiconductor substrate, each transfer electrode being provided in one-to-one relation with one of the photoelectric conversion regions to read a signal charge from a respective photoelectric conversion region and transfer the read signal charge in the column direction; and
wiring portions each connecting transfer electrodes adjacent in a row direction, wherein
the charge transfer regions contains impurities doped so that, in any charge transfer region, a potential of each portion corresponding to an upstream edge of one of the transfer electrodes in a charge transfer direction is lower than remaining portions of the charge transfer region,
a location at which each wiring portion connects into a respective transfer electrode is offset downstream from the upstream edge of the transfer electrode in the charge transfer direction, and
a location of each element-separating region of the semiconductor substrate corresponds to a respective wiring portion.

2. The solid state imaging device according to claim 1, wherein
the location offset downstream from the upstream edge of a respective transfer electrode refers to a location between the upstream edge of the transfer electrode and a central portion of the transfer electrode in the column direction.

3. The solid state imaging device according to claim 1, wherein
in the column direction, each element-separating region is wider than a respective wiring portion located on a region of the insulating film corresponding to the element-separating region.
